(19) United States
(12) Patent Application Publication
(10) Pub. No.: US 2011/0146908 A1
(43) Pub. Date: Jun. 23, 2011

(54) PLASMA PROCESSING APPARATUS AND FOREIGN PARTICLE DETECTING METHOD THEREFOR

(76) Inventors: Hiroyuki KOBAYASHI, Kodaira (JP); Kenji Maeda, Kudamatsu (JP)

(21) Appl. No.: 12/696,072

(22) Filed: Jan. 29, 2010

(30) Foreign Application Priority Data
Dec. 18, 2009 (JP) 2009-287511

(51) Int. Cl. H01L 21/306; G06K 9/00

(52) U.S. Cl. 156/345.24; 382/103

(57) ABSTRACT

The present invention provides a plasma processing apparatus including: a processing chamber; a gas exhaust unit for reducing the pressure of the inside of the processing chamber through a gas exhaust line; and a laser light source for allowing laser light to transmit through an exhaust gas flowing in the gas exhaust line; an I-CCD camera for detecting scattered light caused by foreign particles passing in the laser light; and a foreign particle determination and detection unit for detecting the foreign particles from an image measured by the I-CCD camera, wherein the foreign particle determination and detection unit determines that the foreign particles are detected from the measured image when plural pixels with signals having a predetermined intensity or larger are connected in a substantially straight line.

### CLAIM OF PRIORITY

The present application claims priority from Japanese Patent Application JP 2009-287511 filed on Dec. 18, 2009, the contents of which are hereby incorporated by reference into this application.

### FIELD OF THE INVENTION

The present invention relates to a plasma processing apparatus and a foreign particle detecting method therefor, and more particularly to a plasma processing apparatus including a particle monitor which can be mounted in a mass-produced device and a foreign particle detecting method therefor.

### BACKGROUND OF THE INVENTION

In a manufacturing step of a semiconductor device such as a DRAM or a microprocessor, plasma etching and plasma CVD are widely used. Reduction of the number of foreign particles adhering to a processing target is one of challenges in a process of a semiconductor device using plasma. For example, when foreign particles adhere to a micropattern of a processing target during an etching process, the etching is locally disturbed at the position, causing defect such as disconnection to decrease a yield ratio.

In order to prevent a decrease in the yield ratio caused by contamination of foreign particles in a plasma processing apparatus, a method (called as cleaning or wet cleaning) of disassembling, exchanging, or cleaning a swap part (replacement part) is employed by releasing the apparatus to the atmosphere when the amount of foreign particles generated exceeds a predetermined amount. As the most well known method of measuring the level of contamination caused by the foreign particles, for example, a wafer for inspection is fed to the inside of a processing chamber for simulated discharge, and the number of foreign particles adhering at the time is counted by a wafer surface inspection apparatus.

Further, in another measuring method of the level of contamination caused by the foreign particles, a measuring apparatus capable of measuring the number of foreign particles using an in-situ called as a particle monitor or a particle counter is generally used. The measuring apparatus (hereinafter, referred to as a particle monitor) generally includes at least a laser light source and a light detector for detecting laser scattered by particles. The particle monitor with a simple structure can detect a foreign particle with a particle diameter of about 200 nm, and the particle monitor with a relatively-complicated structure including a high-power laser and a system for synchronizing laser with a light detection system can detect a hundred and several tens of nm in practical use.

The particle monitor for monitoring foreign particles in a processing chamber is described in Japanese Patent Application Laid-Open Publication Nos. 11-330053 and 2000-155086. The former describes a monitor configuration in which laser light is scanned immediately above a wafer by using a mirror and the number of ports used for placing a monitor is only one. The latter describes a method in which a CCD camera is used for a detection unit, and an image measured in a state where no foreign particles are present is subtracted from an image capturing foreign particles to improve the detection sensitivity of the foreign particles. In addition, for example, Japanese Patent Application Laid-Open Publication No. 2005-317900 describes that a particle monitor is provided at a certain point of a bypass exhaust line for exhausting the inside of a processing chamber. Further, Japanese Patent Application Laid-Open Publication No. 2009-117562 describes a method of increasing the detection efficiency of foreign particles by allowing laser light to pass through a position where the foreign particles pass.

### SUMMARY OF THE INVENTION

In a wafer surface inspection apparatus for measuring the number of foreign particles falling onto a wafer, a detection sensitivity has recently been improved to the extent that foreign particles with a particle diameter of, for example, 50 nm can be detected. Therefore, the level of contamination of a processing apparatus is determined on the basis of the number of particles with a particle diameter of, for example, 60 nm or larger in mass production lines of semiconductor devices. For example, there is set a determination criterion that “if the number of foreign particles with a particle diameter of 60 nm or larger exceeds 100, wet cleaning is performed”. It is generally known that the smaller the foreign particles are, the more the foreign particles are generated in a relation of a foreign particle diameter and the amount of foreign particles generated. For example, if the number of foreign particles with a particle diameter of 60 nm or larger is 100, the distribution of the foreign particles shows that the number of foreign particles with a particle diameter of 60 to 80 nm is 80, the number of foreign particles with a particle diameter of 80 to 100 nm is 19, and the number of foreign particles with a particle diameter of 100 nm or larger is 1. Accordingly, the level of contamination caused by the particles is virtually determined on the basis of the amount of foreign particles with a particle diameter of 100 nm or smaller adhering to the wafer.

On the other hand, in the above-described particle monitor capable of detecting the foreign particles with the in-situ, it is difficult to measure particles with a particle diameter of 100 nm or smaller.

If a processing method, as disclosed in, for example, Japanese Patent Application Laid-Open Publication No. 2000-155086, in which an image of a background without the foreign particles is subtracted from an image capturing the foreign particles with a CCD camera is employed in measuring the particles with a particle diameter of 100 nm or smaller, there is little expectation that the detection sensitivity of the foreign particles can be advantageously increased. Therefore, it is difficult to determine the necessity of wet cleaning based only on a measurement result by the particle monitor. Specifically, the particle monitor does not substitute the method of measuring in the wafer surface inspection apparatus using the wafer for inspection, and is only used as an auxiliary monitor. A particle monitor which could be mounted in a mass-produced apparatus capable of measuring foreign particles with a particle a diameter of 100 nm or smaller, for example, 80 nm with high detection efficiency would eliminate the measurement of the number of foreign particles using the wafer for inspection. Thus, costs of the wafer for inspection could be reduced. Further, the measurement of the number of foreign particles using the wafer for inspection is performed at a predetermined timing, for example, twice a day. However, there is a possibility that unexpected mass generation of particles as in the case where there is a one in ten chance of generation of particles can not be quickly detected in the measurement twice a day or so, and thus, the manufacturing process is probably continued for a few days. A particle monitor capable of constantly monitoring the level of foreign particles with required accuracy would quickly recognize unexpected generation of foreign particles and advantageously prevent a yield ratio from decreasing at an early stage.

An object of the present invention is to provide a plasma processing apparatus in which a particle counter capable of detecting foreign particles with a particle diameter of 100 nm or smaller with high efficiency is mounted.

Another object of the present invention is to provide a plasma processing apparatus in which a particle monitor capable of constantly monitoring the level of foreign particles with required accuracy is mounted and a foreign particle detecting method therefor.

The representative aspect of the present invention is shown as follows. The present invention provides a plasma processing apparatus including: a processing chamber; a high-frequency electric power for generating plasma; a gas supplying unit for supplying a gas; a gas exhaust unit for reducing the pressure of the inside of the processing chamber through a gas exhaust line; a pressure-adjusting valve for adjusting the pressure of the inside of the processing chamber; and a sample stage on which a processing target is placed, the apparatus further including: a laser light source for allowing laser light to transmit through the gas exhaust line; an I-CCD camera for detecting scattered light caused by foreign particles passing in the laser light; and a foreign particle determination and detection unit for detecting the foreign particles from an image measured by the I-CCD camera, wherein the foreign particle determination and detection unit determines that the foreign particles are detected from the measured image when plural pixels with signals having a predetermined intensity or larger are connected in a substantially straight line.

According to the present invention, an image obtained by the I-CCD camera is processed by the image processing program. If a substantially-straight pixel line is present, in other words, plural pixels connected in a substantially straight line are detected on the basis of the states of the signal intensities of the respective pixels, it is determined that the foreign particles are present. Therefore, it is possible to easily detect the foreign particles with a particle diameter of 100 nm or smaller. In addition, measurement of the number of foreign particles using a wafer for inspection is not necessary. Accordingly, it is possible to provide a plasma processing apparatus in which a particle monitor capable of constantly monitoring the level of foreign particles with required accuracy is mounted and a foreign particle detecting method therefor.

### BRIEF DESCRIPTION OF THE DRAWINGS

Exemplary embodiments of the present invention will be described in detail based on the following figures, wherein:

FIG. 1 is a longitudinal cross-sectional view of a plasma processing apparatus in which a particle monitor unit is mounted according to a first embodiment of the present invention;

FIG. 2A is a general top cross-sectional view of the particle monitor unit according to the first embodiment;

FIG. 2B is a general side cross-sectional view of the particle monitor unit according to the first embodiment;

FIG. 3 is a diagram for explaining foreign particle diameter dependence of scattered light intensity (a) caused by foreign particles and stray light;

FIG. 4 is a flowchart of a foreign particle determination program in the first embodiment;

FIG. 5A is a diagram showing an image example in which the average number of photons of stray light entering one pixel of a CCD device in an I-CCD is 1;

FIG. 5B is plotted graphs in each of which the horizontal axis represents a signal intensity and the vertical axis represents the number of pixels with the corresponding signal intensity in the image of FIG. 5A;

FIG. 6 is a diagram showing a relation between an image number and the total value of signal intensities of all pixels;

FIG. 7A is a diagram showing a measurement example in which scattered light caused by the foreign particles is relatively strong;

FIG. 7B is plotted graphs in each of which the horizontal axis represents a signal intensity and the vertical axis represents the number of pixels with the corresponding signal intensity in the image of FIG. 7A;

FIG. 8A is a diagram showing an example of a measured image in the case where the intensity of the scattered light caused by the foreign particles is weak;

FIG. 8B shows a correlation between the number of pixels and a signal intensity in the image of FIG. 8A;

FIG. 9A is a diagram for explaining a state in which plural pixels with signals having a predetermined intensity or larger are connected in a substantially straight line;

FIG. 9B is a diagram for explaining a procedure of connecting a certain base point with points within a predetermined range;

FIG. 9C is a diagram showing a state in which a predetermined number or larger of pixels are connected and extracted within the predetermined range from the certain base point in FIG. 9B;

FIG. 9D is a diagram showing determination of detection of the foreign particles by integrating and comparing the signal intensities of the respective pixels in one direction for the points of FIG. 9B;

FIG. 10A is a diagram showing a method of extracting a trajectory of the foreign particles while pixels with a signal intensity of 200 or larger are shown in white and pixels with a signal intensity of less than 200 are shown in black;

FIG. 10B is a diagram showing a result obtained by extracting the trajectory of the foreign particles shown in FIG. 10A;

FIG. 11A shows a CCD image in which the foreign particles with a relatively-high velocity are measured;

FIG. 11B is a diagram showing a result obtained by extracting the trajectory of the foreign particles shown in FIG. 11A;

FIG. 12A is diagrams in which an image obtained by subtracting background light shown in (A) similar to FIG. 5A from the image of FIG. 5A is shown as (B), as a comparative example;

FIG. 12B is diagrams showing a relation between a signal intensity and the number of pixels in (B) of FIG. 12A;

FIG. 13A is a diagram showing an image obtained by subtracting (A) of FIG. 12A from FIG. 8A, as a comparative example;

FIG. 13B is diagrams showing a relation between a signal intensity and the number of pixels in the image of FIG. 13A;

FIG. 14A is a general top cross-sectional view of an apparatus in which an observed area is divided into plural areas according to a second embodiment;

FIG. 14B is a general side cross-sectional view of the apparatus in which the observed area is divided into the plural areas;

FIG. 15A is diagrams, each showing an example of time changes of signals in the case where the foreign particles are captured by three detectors;

FIG. 15B is diagrams, each showing an example of time changes of signals only by background light;

FIG. 16 is a top cross-sectional view of an exhaust line in a detection device of the foreign particles passing in the exhaust line according to a third embodiment of the present invention;

FIG. 17 is a cross-sectional view of the pipe shown in FIG. 16;

FIG. 18A is a side view of an apparatus in which plural foreign particle detectors, each including one detector and one laser light source, are provided at the exhaust line;

FIG. 18B is a top view of the apparatus of FIG. 18A; and

FIG. 19 is a diagram showing an example of measuring the front side of the scattered light caused by the foreign particles.

### DETAILED DESCRIPTION OF THE EMBODIMENT

A plasma processing apparatus according to an aspect of the present invention includes a processing chamber, a unit for supplying a gas to the processing chamber, an exhaust unit for reducing the pressure of the processing chamber, a pressure-adjusting valve for adjusting the pressure of the inside of the processing chamber, and a sample stage on which a processing target is placed. In the plasma processing apparatus, laser light with a laser power density of 100 mW/mm² or larger is allowed to pass immediately beneath a gap generated when the pressure-adjusting valve adjusts the pressure (when valve is not fully open), the laser light scattered by foreign particles is detected by a CCD camera (I-CCD camera) with an image intensifier, and there is provided a signal processing system which determines that the foreign particles are detected when plural pixels with signals having a predetermined intensity or larger can be fitted in a substantially straight line in a two-dimensional image obtained by the I-CCD camera.

Hereinafter, embodiments of a plasma processing apparatus and a foreign particle detecting method therefor to which the present invention is concretely applied will be described in detail with reference to the drawings.

### First Embodiment

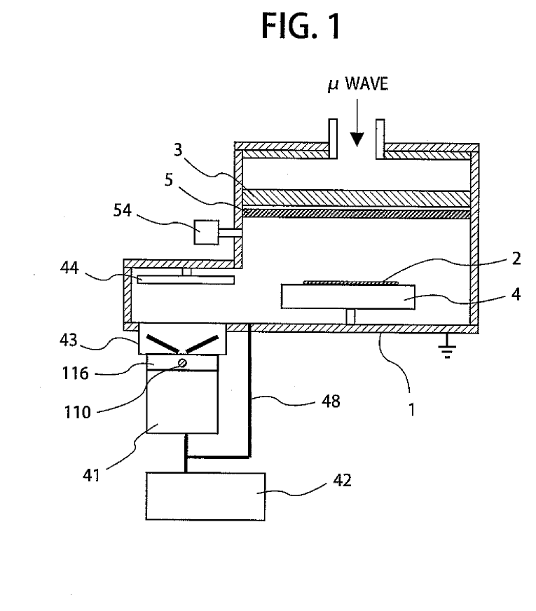

First of all, a first embodiment of the present invention will be described. FIG. 1 shows an example of a plasma processing apparatus in which a particle monitor unit of the embodiment is mounted. In the first place, the entire configuration of the plasma processing apparatus that is an application target of the present invention will be described. A waveguide for introducing a microwave is provided at an upper portion of a processing chamber 1. Further, a top plate 3 through which the microwave transmits and a shower plate 5 for supplying a gas are provided at upper portions of the processing chamber 1. A sample stage 4 for placing a wafer 2 that is a processing target is provided at a lower portion of the processing chamber 1 while facing the shower plate 5. A processing gas supplying system for supplying a gas to the inside of the processing chamber, a high-frequency electric power for generating plasma, and a high-frequency electric power for applying a bias to the processing target are not illustrated. In a main exhaust line of the processing chamber 1, there are provided a turbo-molecular pump 41 and a dry pump 42 for reducing the pressure of the inside of the processing chamber. Further, in order to adjust the pressure of the inside of the processing chamber, a pressure-adjusting valve unit 43 is provided above the turbo-molecular pump 41 in the main exhaust line. A particle monitor unit 116 for detecting particles generated within the processing chamber is provided between the turbo-molecular pump 41 and the pressure-adjusting valve unit 43. In order to measure the pressure of the inside of the processing chamber, a vacuum gauge 54 is provided at the processing chamber 1. Further, a bypass exhaust line 48 used for initial exhaust when vacuuming the processing chamber after the processing chamber is released to the atmosphere for cleaning is provided between the processing chamber 1 and the dry pump 42. The reference numeral 44 denotes a main valve. It should be noted that the main exhaust line and the bypass exhaust line are collectively defined as an exhaust system of the processing chamber.

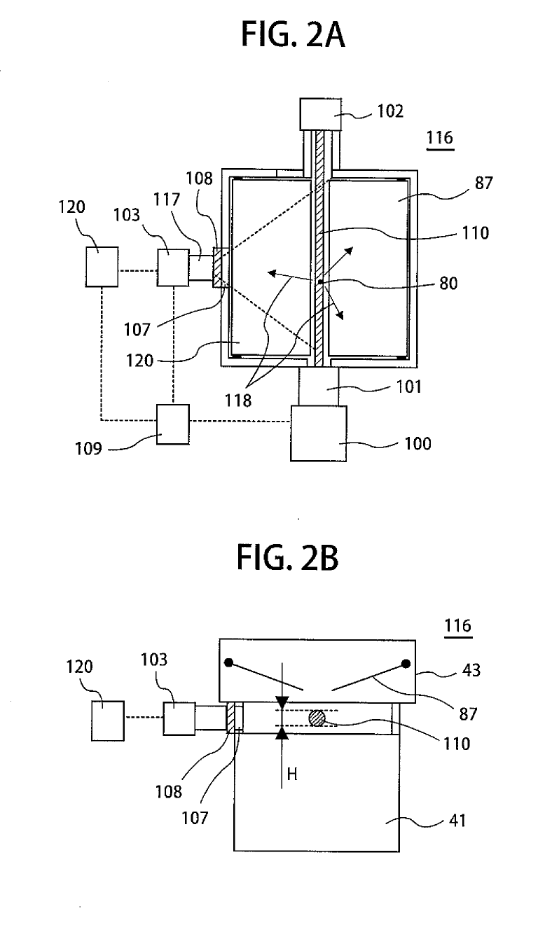

Next, a configuration of the particle monitor unit 116 will be described with reference to FIG. 2 (FIG. 2A and FIG. 2B). FIG. 2A shows a general top cross-sectional view of the particle monitor unit and FIG. 2B shows a general side cross-sectional view of the particle monitor unit 116. The particle monitor unit includes a CCD camera (CCD camera (I-CCD camera) 103 with an image intensifier) and a foreign particle determination and detection unit. Specifically, the laser light is irradiated immediately beneath a gap between flappers, and scattered light (photon) scattered by particles is measured by the CCD camera 103. Further, the particle monitor unit includes a personal computer 120 having a CPU and a memory, as a foreign particle determination and detection unit, and has a function of detecting and determining generation of particles through processing of an image obtained by the CCD camera by executing a program on the memory. In other words, the particle monitor unit 116 has a function of determining that foreign particles are detected when pixels with signals having a predetermined intensity or larger are connected in a substantially straight line in the image measured by the I-CCD camera.

A pulse oscillation-type laser light source is used for a laser light source unit 100, the beam diameter and the beam cross-sectional shape of the laser light oscillated by the laser light source are adjusted through a beam cross-sectional shape adjusting optical system 101 including a beam expander and the like. In addition, the power density of the laser light after being adjusted to a predetermined cross-sectional shape is 100 mW/mm² or larger in the width (Full Width at Half Maximum (FWHM)) of the laser cross section. The height H (FWHM) of the cross section of the laser light is about 10 mm.

The laser light passes immediately beneath a gap between two flappers of the pressure-adjusting valve 43 (butterfly valve) and is terminated at a beam damper 102. A part of scattered light 118 generated due to a foreign particle 80 traversing laser light 110 enters a light collecting optical system 117, and is detected by the I-CCD camera 103. As shown in Japanese Patent Application Laid-Open Publication No. 2009-117562, in a state where a gas is allowed to flow from the shower plate, many of foreign particles generated by being removed from inner walls of the processing chamber are delivered on the exhaust side along the gas flow. Since many of foreign particles pass through the gap between the flappers to enter the inside of the turbo-molecular pump 41, there is a high probability that the foreign particles pass through the laser light 110 passing immediately beneath the gap between the flappers 87. Specifically, the laser light is irradiated onto a potential area where the foreign particles pass, so that the detection efficiency of the foreign particles is enhanced.

In order to reduce plasma light entering the I-CCD camera 103, a band-pass filter 108 through which only light with a wavelength similar to that of the laser light passes is provided at the light collecting optical system 117. Further, a gate of an image intensifier (II) of the I-CCD camera is in synchronization with laser pulses by a pulse generator 109 controlled by the personal computer 120. Accordingly, plasma light (That is, noise cause by the plasma light) is not recorded into a CCD device of the I-CCD camera between pulses of laser, namely, at a timing when the laser light is not oscillated.

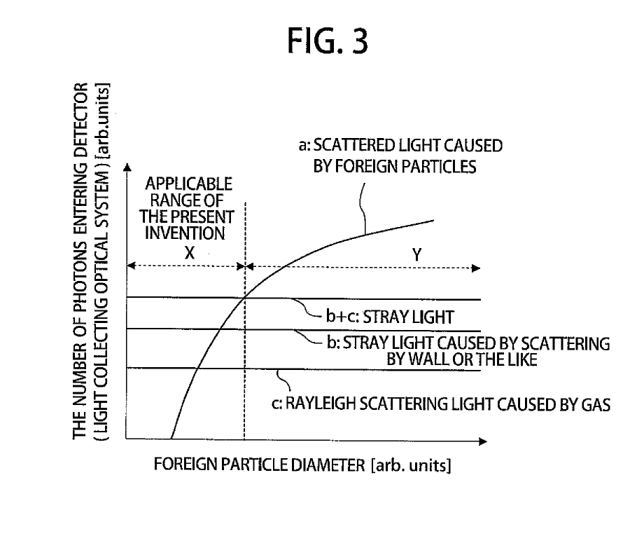

Next, the scattered light caused by the foreign particles and stray light other than the scattered light will be described. FIG. 3 is a diagram for explaining foreign particle diameter dependence of scattered light intensity (a) caused by foreign particles and stray light. The horizontal axis represents a particle diameter of a foreign particle and the vertical axis represents the number of photons entering the light collecting optical system. Here, the stray light indicates scattered light of laser generated due to a factor other than the foreign particles. Light scattering caused by the foreign particles with a particle diameter of about 100 nm or smaller becomes Rayleigh scattering, and thus, the intensity of the scattered light caused by the foreign particles is proportional to the sixth power of the foreign particle diameter. Specifically, the intensity of the scattered light of laser is reduced to about hundredth by the foreign particles with a particle diameter of 100 nm, as compared to those with a particle diameter of 200 nm.

The stray light is generally generated by: (b) scattering and reflection at a laser introduction window or a beam damper; and (c) Rayleigh scattering caused by a gas. The intensity of the Rayleigh scattering light caused by a gas is proportional to the pressure of a gas supplied to the inside of the processing chamber. Accordingly, if the pressure is reduced to half, the intensity of the stray light caused due to the Rayleigh scattering caused by a gas is also reduced to half. It should be noted that if simply referred to as stray light, it implies the total of (b) and (c) in the following description.

In order to detect the foreign particles, it is desirable that the absolute intensity of the scattered light caused by the foreign particles is large and the intensity of the scattered light caused by the foreign particles is much larger than the intensity of the stray light. In particular, if a signal by the foreign particles is not sufficiently larger than that by the stray light when using a light detector including a photomultiplier tube (PMT) without position resolution, it is difficult to detect the foreign particles in general. This fact corresponds to an area Y in FIG. 3.

On the other hand, if an image process is performed by using a detector with position resolution such as I-CCD, it is possible to detect the foreign particles even in the case where the number of photons of the stray light entering the light collecting optical system is larger than that of the scattered light caused by the foreign particles (an area X in FIG. 3). Hereinafter, a procedure of detecting the foreign particles will be described in detail.

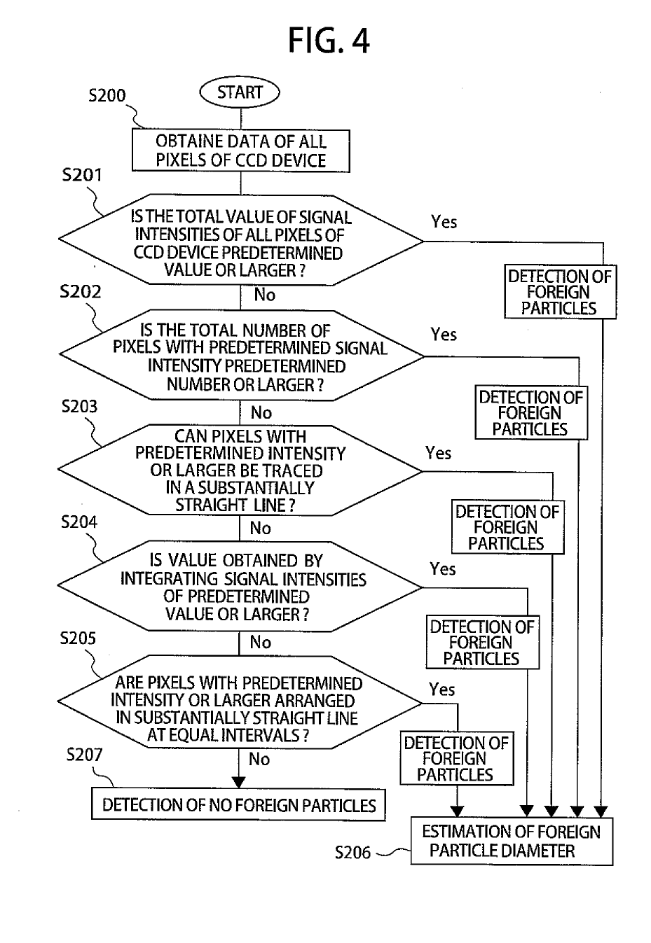

According to an aspect of the present invention, in the foreign particle determination and detection unit of the particle monitor unit 116, data of all pixels of the CCD device detected by the I-CCD camera 103 are obtained (S200) as shown in FIG. 4, and then, a detecting process of the foreign particles is performed in five steps (S201 to S205) by an image processing program having a foreign particle determination and detection function. In the case where the foreign particles are detected in any one of the steps of S201 to S206, a “foreign particle diameter” is estimated (S206). In the case where no foreign particles are detected in any one of the steps of S201 to 5206, it is determined as “detection of no foreign particles” (S207), and the process is completed.

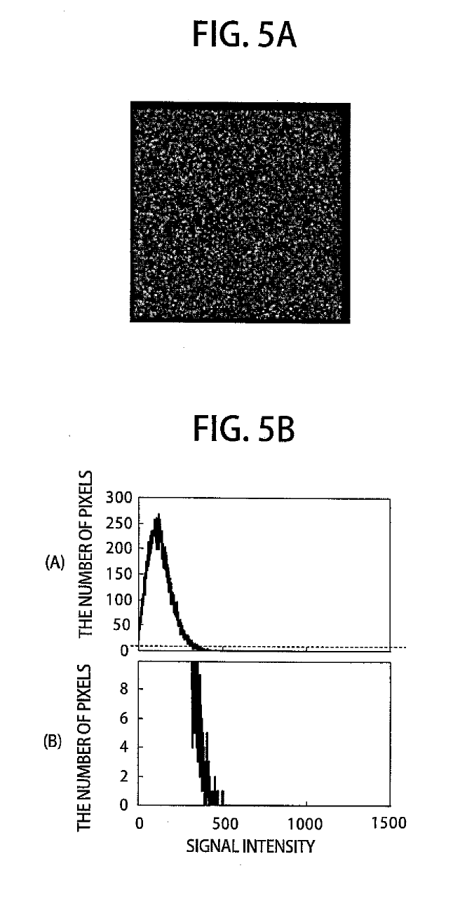

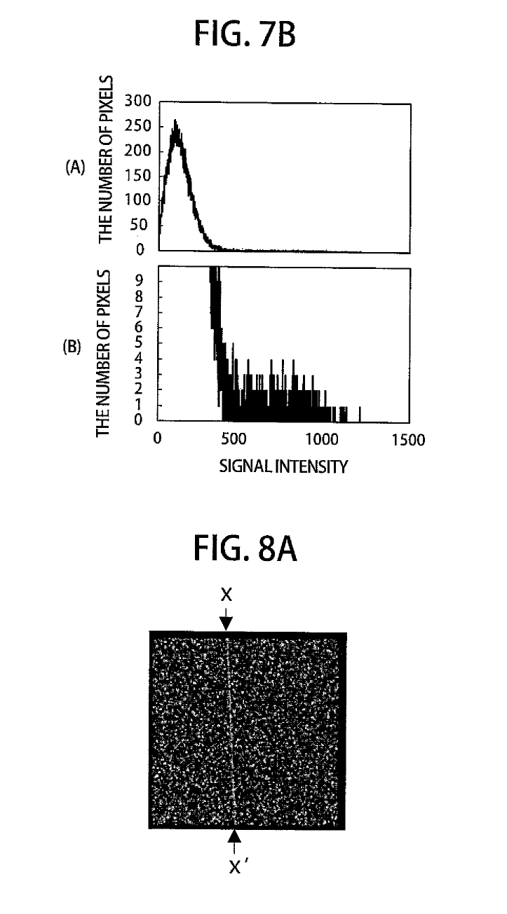

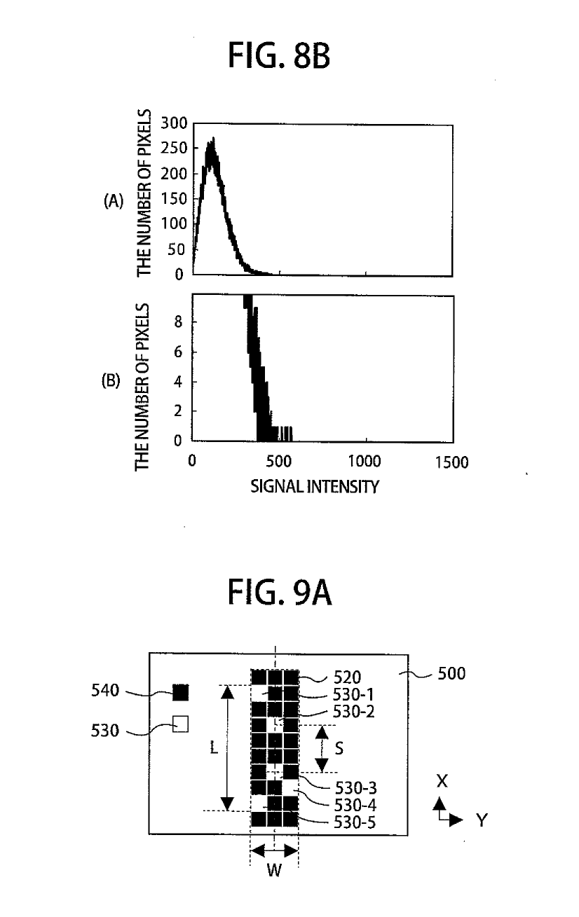

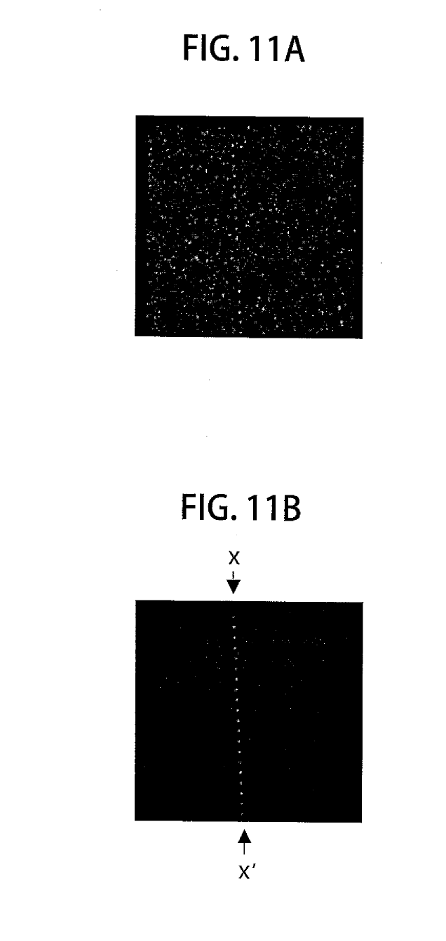

The data of all pixels of the CCD device obtained in 5200 are data of all pixels of one screen detected by the I-CCD camera 103 as shown in measurement examples of, for example, FIG. 5A, FIG. 7A, FIG. 8A, and FIG. 11A. It should be noted that the width of a spatial region observed by one pixel is 0.05 mm in the illustrated examples.

FIG. 5A shows an image example in which the average number of photons of the stray light entering one pixel of the CCD device in the I-CCD is 1. In other words, FIG. 5A shows an image example in which no foreign particles are detected. The number of pixels is 200×200 in height and width, namely, 40000 in total. The number of photons of the stray light entering the light collecting optical system is about 40000 in total. Here, the image is shown while being standardized in such a manner that when one photon enters the light collecting optical system, the half-value width corresponds to a few pixels and the signal intensity in the middle pixel is up to 100 in the CCD device. Recording of a signal of one photon entering the I-CCD camera across a few pixels in the CCD device is mainly caused by the image intensifier. In FIG. 5A, black represents 0 in signal intensity, and white represents 400 or larger in signal intensity, so that signal intensities between 0 and 400 are displayed in a gray scale.

FIG. 5B is plotted graphs in each of which the horizontal axis represents a signal intensity and the vertical axis represents the number of pixels with the corresponding signal intensity in FIG. 5A. The lower graph of FIG. 5B shows a graph obtained by enlarging points 0 to 10 of the vertical axis in the upper graph of FIG. 5B. The number of pixels with a signal intensity of 100 to 200 is about 200 to 250, whereas the number of pixels with a signal intensity far beyond 500 is 0. The total value of signal intensities of all pixels is about 5 million.

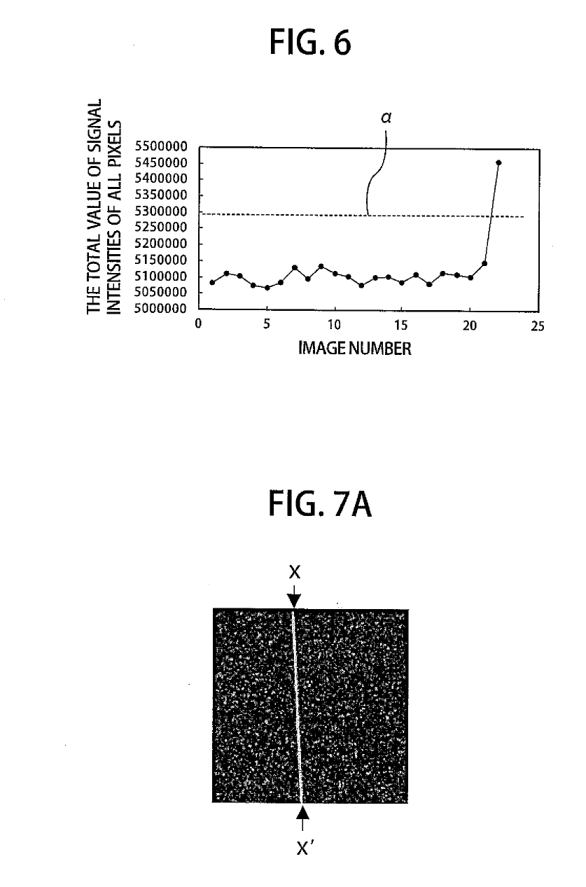

The stray light is random incident light, and signal intensification by the image intensifier also involves random elements. Accordingly, the total value of signal intensities of all pixels does not absolutely become a constant value depending on a shot image, and has a certain level of fluctuation as shown in, for example, FIG. 6. In FIG. 6, the horizontal axis represents an image number and the vertical axis represents the total value of signal intensities of all pixels.

It should be noted that a range of image numbers 1 to 20 in FIG. 6 represents an image as shown in FIG. 5A in which no foreign particles are captured. On the other hand, the image number 21 in FIG. 6 represents a case in which relatively-weak scattered light caused by the foreign particles is measured as shown in FIG. 8A, and the image number 22 represents a case in which relatively-strong scattered light caused by the foreign particles is measured as shown in FIG. 7A, namely, the total value of signal intensities of all pixels exceeds a constant threshold value a.

Next, a first detection step (S201) of the foreign particles will be described. In S201, the presence or absence of the foreign particles is determined based of a simple criterion of “whether or not the total value of signal intensities of all pixels of the CCD device is a predetermined value or larger”. In S201, the presence or absence of the foreign particles is determined in a measurement example in which the scattered light caused by the foreign particles is relatively strong enough to exceed the threshold value a. Specifically, the presence or absence of the foreign particles is determined in the case where the image obtained in S200 corresponds to the image shown in FIG. 7A, namely, the image number 22 in FIG. 6.

As shown in FIG. 7A, a trajectory of the foreign particles between X to X′ is shown in a substantially straight line. Here, the measurement area is 10×10 mm. Specifically, the observed range of one pixel is 0.05×0.05 mm. A laser pulse frequency is 10 kHz, the velocity of the foreign particles is about 0.5 m/s, and a delivering direction is substantially straight. The average number of photons entering the light collecting optical system among those scattered by the foreign particles for each laser pulse is 5. The moving distance of the foreign particles per one laser pulse is about 0.05 mm, and thus, an image of each foreign particle is moved to the adjacent pixel on the CCD every shot of a laser pulse. In this case, a trajectory of the foreign particles is captured as a continuous straight trajectory. The number of photons of the stray light entering the light collecting optical system is 40000 as similar to FIG. 5.

As shown in FIG. 7A, in the case where the signal intensity of the pixels capturing the scattered light caused by the foreign particles is relatively larger than that (FIG. 5A) of the pixels capturing only the stray light, it is determined whether or not the signal intensity exceeds the constant threshold value a as shown in FIG. 6. Accordingly, detection of the foreign particles can be determined on the basis of the total value of signal intensities of all pixels. Further, even in the case where the signal intensity caused by one foreign particle is weak (That is, in the case of a minute foreign particle), if plural foreign particles are measured at the same time, detection of the foreign particles can be determined by the same method on the basis of the total value of the signal intensities. Such a process is performed in S201.

Next, a second detection process (S202) of the foreign particles will be described. In this process, the presence or absence of the foreign particles is determined for the images as shown in FIG. 7A and FIG. 7B by a method different from S201, namely, base on a determination criterion of whether or not the total number of pixels with a predetermined signal intensity is a predetermined number or larger. In the example of FIG. 7B, the number of pixels with a signal intensity of 500 or larger is apparently increased as compared to FIG. 5B in which no foreign particles are detected. Therefore, if it is assumed that “the foreign particles are observed when the total number of pixels with a predetermined signal intensity or larger is a predetermined number or larger”, detection of the foreign particles can be determined. Specifically, for example, it may be defined in S202 as “the foreign particles are measured when the total number of pixels with a signal intensity of 700 or larger is 200 or larger”.

The method of S202 is effective in the case of the large signal intensity of the scattered light, namely, in detection of the foreign particles with a relatively-large particle diameter. On the other hand, it is difficult, as compared to S201, to determine “detection of the foreign particles” when the intensity of the scattered light is weak, namely, the plural foreign particles with a relatively-small particle diameter are captured. Thus, roughly speaking, in the case where it is determined that the foreign particles are detected in both of S201 and S202, the foreign particles with a large particle diameter are detected. If it is determined that the foreign particles are detected in S201, but no foreign particles are detected in S202, plural minute foreign particles are detected at the same time, which helps to estimate the particle diameters of the detected foreign particles in S206.

Next, in a third detection process (S203) of the foreign particles, the foreign particles are measured when the scattered light caused by the foreign particles in the image obtained in S200 is relatively weak and the foreign particles can not be detected in S201 and S202. Here, detection of the foreign particles is performed based on a determination criterion of “whether or not pixels with a constant signal intensity or larger can be traced in a substantially straight line” when the intensity of the scattered light caused by the foreign particles is weak (when of the plural foreign particles are not observed at the same time).

An example of a measured image in this case is shown in FIG. 8A. A linear trajectory of the foreign particles is captured between X and X′. The observed area and conditions, the velocity of the foreign particles, and the like are the same as those in FIG. 7, and the average number of photons entering the light collecting optical system among those scattered by the foreign particles for each laser pulse is 1 (That is, one fifth of the case in FIG. 7). In this case, the total value of signal intensities of all pixels shows that of the image number 21 in FIG. 6 as in S201, and is smaller than a in FIG. 6. Accordingly, there is no significant difference between the total value in FIG. 8A and that of signal intensities of an image without the foreign particles.

Further, FIG. 8B shows a correlation between the number of pixels and a signal intensity. However, FIG. 8B is not largely different from FIG. 5B, and it is difficult to detect the foreign particles even by the method of S202. Therefore, the trajectory of the foreign particles is traced on the pixels by the following method to detect the foreign particles in S203.

As shown in FIG. 1, in the case where the laser light 110 is allowed to pass beneath the butterfly valve 43 to observe the scattered light from the side face, a trajectory of the foreign particles forms a substantially straight line. As described in, for example, the article “Thin Solid Films 516, (2008), 3469-3473” as an example of a case in which the trajectory does not form a straight line, the foreign particles moving immediately above a processing target during plasma discharge are delivered in a direction parallel to the processing target while being vertically oscillated.

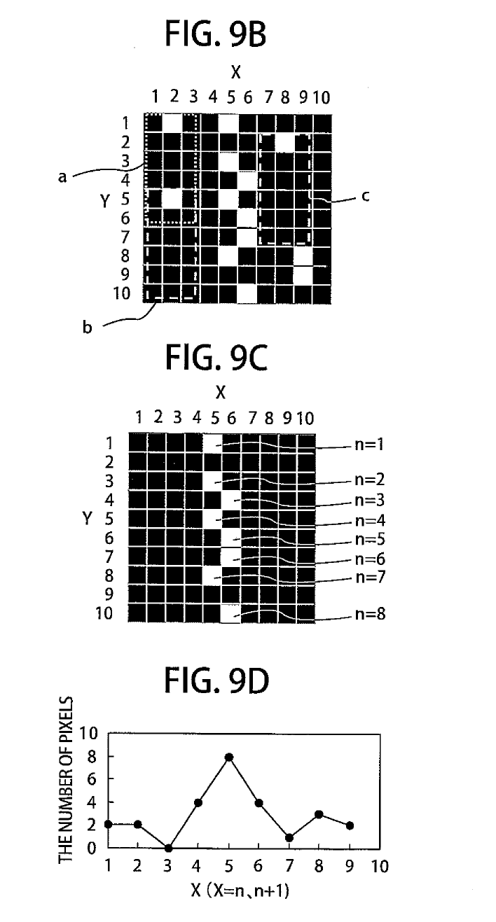

In the case where it is predicted that the trajectory of the foreign particles forms a substantially straight line, it is determined whether or not pixels with a certain signal intensity or larger can be traced in a substantially straight line, which helps to determine either a noise caused by the stray light or a signal caused by the foreign particles. This method will be described using FIG. 9A to FIG. 9D.

FIG. 9A is a diagram for explaining a state in which plural pixels with signals having a predetermined intensity or larger are connected in a substantially straight line, in other words, a state in which “plural pixels with a certain signal intensity or larger can be traced in a substantially straight line”. The foreign particles are moved with the gas flow, and the trajectory thereof substantially follows the gas flow. Specifically, in the case where the foreign particles are contained in the image obtained in S200, the trajectory thereof generally forms a substantially straight line along one axis of the image, namely, the vertical (Y) axis in this case or an axis with a similar angle (about ±10 degrees). In the case where pixels 530 (530-1 to 530-5) with a predetermined signal intensity or larger are present across a predetermined length L with predetermined pitches S or shorter in a rectangular area 520 with a predetermined width W along the arbitrary Y-axis in an image 500 obtained in S200, it is determined that a substantially-straight pixel line is present, in other words, the plural pixels are substantially connected in a straight line. Pixels 540 in FIG. 9A show pixels with a signal intensity lower than a predetermined value.

As an example, the predetermined width W of the rectangular area 520 corresponds to a range covering one pixel or less relative to the middle pixel line in each direction orthogonal to the X-axis, the pitch S corresponds to a range covering two pixels or less in each of upper and lower directions along the middle X-axis, and the predetermined length L corresponds to 5 pixels along the X-axis. Alternatively, the width W may correspond to 2 pixels or less, the pitch P may correspond to 5 pixels or less, and the length L may correspond to 30 pixels or more according to measurement conditions. If a pixel line in a substantially straight form with the predetermined length L is detected under such conditions, it is determined as a trajectory of the foreign particles. The pixel line is extracted and data of the pixels 530 which do not satisfy the conditions for the pixel line are deleted, so that data of the substantially-straight pixel line can be obtained.

A more concrete example will be described in FIG. 9B. FIG. 9B shows 100 pixels in a range of 10×10. For example, pixels with a signal intensity of 200 or larger are shown in white, and pixels with a signal intensity of less than 200 are shown in black. At Y=1, the pixels with a signal intensity of 200 or larger are searched from X=1 in order. At a point (X, Y)=(2, 1), the corresponding pixel is present. Next, assuming that the coordinate of the pixel is (Xₙ₌₁, Yₙ₌₁)=(2, 1), the pixels with a signal intensity of 200 or larger are searched in a range of ΔX=±1 and γY=5 or smaller, namely, (Xₙ₌₂, Yₙ₌₂)=(Xₙ₌₁+ΔX(−1=ΔX=1), Yₙ₌₁ΔY(ΔY=5)) (the range represented by “a” in FIG. 9B). The corresponding pixel is present at a point (X, Y)=(2, 5). Next, assuming that the position is a base point, the pixels are searched in a range of ΔX=±1 and ΔY=5 or smaller (“b” in FIG. 9B). However, since the corresponding pixels are not present, no more pixels can be connected. In addition, even in the case of (X, Y)=(8, 2) as a base point, the pixels with a signal intensity of 200 or larger are not present in a range of ΔX=±1 and ΔY=5 (the range represented by “c” in FIG. 9B). Thus, the pixels can not be connected. On the contrary, assuming that a pixel (X, Y)=(5, 1) is a base point (n=1), the pixels are searched in a range of ΔX=±1 and ΔY=5. The corresponding pixel (n=2) is present at a point (X, Y)=(5, 3). Further, assuming that the position is a base point, the pixels are searched in a range of ΔX=±1 and ΔY=5. The pixel (n=3) can be located at a point (X, Y)=(6, 4).

This procedure is repeated to extract the predetermined number (for example, 5) or larger of pixels in total which can be connected within a predetermined range from a certain base point, and the result is shown in FIG. 9C. In FIG. 9C, 8 pixels (n=1 to 8) can be connected in a substantially straight line with a length corresponding to 10 pixels from the first base point. With such an operation, the trajectory of the foreign particles can be extracted. It is obvious that the determination criterion includes a predetermined length or larger of the substantially straight line when the pixels are connected in a substantially straight line.

The following three points are determination criteria of detection of the foreign particles.
(1) Within a predetermined range of ΔX and ΔY from a pixel (n-th), as a base point, with a predetermined signal intensity or larger, the next pixel (n+1'th) with a predetermined signal intensity or larger is searched.
(2) The operation of (1) can be repeated predetermined times (n) or more (n becomes a predetermined number or larger).
(3) The length of a substantially straight line is a predetermined length or longer.

Specifically, a substantially straight line connecting a pixel (n=1) at the start point and a pixel (n=maximum value) at the end point has a predetermined length or longer.

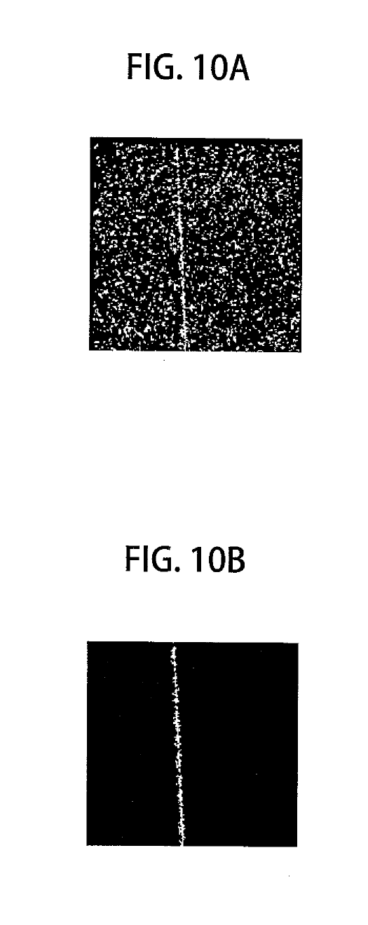

FIG. 10 shows a result obtained by analyzing FIG. 8A with the similar method. In FIG. 10A, pixels with a signal intensity of 200 or larger are shown in white, and pixels with a signal intensity of less than 200 are shown in black. In FIG. 10A, it is determined whether or not pixels with a signal intensity of 200 or larger are present in a predetermined range defined as, for example, Xₙ₊₁=Xₙ+ΔX(ΔX=±2). Yₙ₊₁=Yₙ±ΔY(ΔY=5) starting from the first base point, and it is determined whether or not the corresponding pixels can be connected in a straight line. In addition, if the number of pixels with a signal intensity of, for example, 200 or larger is 50 or larger (namely, n=50) on the straight line, it is determined as the trajectory of the foreign particles. Accordingly, the trajectory of the foreign particles can be extracted as shown in FIG. 10B. Such determination is performed in S203.

Next, in a fourth detection process (S204) of the foreign particles, the foreign particles, as shown in FIG. 8A, which cause relatively-weak scattered light are measured by a method different from S203. Here, the presence or absence of the foreign particles are determined based on “whether or not a value obtained by integrating the signal intensities of the respective pixels in one direction is a predetermined value or larger”. Specifically, in the case where it can be predicted that the trajectory of the foreign particles forms a straight line, detection of the foreign particles can be determined even by integrating and comparing the signal intensities of the respective pixels in one direction for each predetermined rectangular area in, for example, FIG. 9B. This result is shown in FIG. 9D. In FIG. 9D, the vertical axis represents the number of pixels with a signal intensity of 200 or larger in one direction, namely, in the lines of X=n and X=n+1, and the horizontal axis represents an X-coordinate n. As can be understood from FIG. 9D, the number of pixels with a signal intensity of 200 or larger in the lines of X=5 and X=6 are significantly larger than the others, and thus, the presence or absence of the foreign particles can be determined even by such a method. The process of S204 is simple, but if the trajectory forms a curved line, the detection capability is decreased as compared to S203.

Next, a fifth detection process (S205) of the foreign particles will be described in the case where the foreign particles can not be detected in S201 to S204 because the scattered light caused by the foreign particles in the image obtained in S200 is relatively weak due to the high velocity of the foreign particles and a continuous straight line is not formed. Here, detection is performed based on “whether or not plural pixels with a certain signal intensity or larger are arranged in a substantially straight line at substantially-equal intervals”. As similar to FIG. 5, in the case where, for example, 200×200 pixels observe a range of 10 mm×10 mm, the frequency of a laser pulse is 10 kHz, and the velocity of the foreign particles is 5 m/s, the distance of the foreign particles moving during one laser pulse is 0.5 mm. Since an observed range per one pixel is 0.05 mm×0.05 mm, the scattered light caused by the foreign particles is recorded about every 10 pixels, and the trajectory of the foreign particles is observed as a dotted line. This example is shown in FIG. 11A. The trajectory of the foreign particles is captured in a dotted line between X and X′ in FIG. 11A. The average number of stray light is one in 10 pixels, and 4000 photons enter as a whole.

The pixels with a signal intensity of 100 or larger are selected in a range of Y=1 to 20 of Yₙ₌₁ from the first base point Xₙ₌₁, and it is determined whether or not the next point with a signal intensity of 100 or larger can be located in a range of Xₙ₌₁=Xₙ+ΔX(−2=ΔX=2), Yₙ₌₁=Yₙ+ΔY(8=ΔY=12). Then, if only 15 or more pixels which can be connected are extracted, an image shown in FIG. 11B can be obtained as a result. In the case where the level of the stray light shows a certain value or smaller, the probability that random noises are accidentally arranged on a straight line at equal intervals is very low. Accordingly, weak scattered light caused by minute foreign particles can be detected while reducing the probability of false detection. However, since the upper and lower limits are set to ΔY in S205 to narrow the searching range, it is effective if the range of ΔY is selected in accordance with the estimated velocity of the foreign particles. Further, in the case where the velocity of the gas flow is not constant in the observed range, it is desirable to change ΔX and ΔY for each coordinate in accordance with distribution of the velocity of the gas flow.

Through any one of five steps (S201 to S205) related to detection of the foreign particles shown in FIG. 4, “detection of the foreign particles” can be determined.

Next, the particle diameter of the foreign particles is estimated based on the intensity of the scattered light caused by the foreign particles and the velocity to be estimated (S206).

If none of five steps are satisfied, it is determined as detection of no foreign particles (S207), and the process of detection of the foreign particles is completed.

Next, the size of the cross section of laser and the frequency of a laser pulse used in detection of the foreign particles of the present invention will be described. It is conceivable that the velocity of the foreign particles in the processing chamber is generally slower than several tens of m/s, excluding high-speed components in the foreign particles bounced back by the turbo-molecular pump. This is derived from a gas flow velocity of several tens of m/s or slower. Therefore, it is desirable that the width (H in FIG. 2) of the laser light in the travelling direction of the foreign particles in the observed area is in the relation of the following formula (1) wherein the gas velocity or the estimated velocity of the foreign particles in the observed area is V, the frequency of laser is F, and the width of the laser light is H.

H=5×V/F (1)

Assuming that the velocity of the foreign particles is 10 m/s and the frequency of laser is 10 kHz, H=5×10 [m/s]/10000 s⁻¹] is obtained, resulting in H=0.005 [m]

If H=5 mm, the trajectory of the foreign particles is observed as five points arranged at equal intervals. It is obvious that this is observed under the condition that the number of photons of the scattered light which is caused by the foreign particles and enters the light collecting optical system is sufficiently larger than 1 in one laser pulse.

In order to increase the scattered light which is caused by the foreign particles and enters the light collecting optical system, it is effective to increase the power density and power energy of the laser light.

If a unit cross-section energy per one laser pulse is about 10 μJ/mm² or larger, a few photons which are caused by the foreign particles with a particle diameter of about 80 nm and enter the light collecting optical system can be expected per one laser pulse in a relatively-large camera lens provided at a position apart from the laser light by several tens of cm. Thus, assuming that an average energy per a unit cross-section of laser is P, it is desirable that the relation of the following formula (2) is satisfied.

P [mW/mm²]=1×10⁻²×F [Hz] (2)

If F=10 kHz, P is 100 mW/mm² or larger. In addition, several tens of cm of the height H of the laser light is not desirable because the distance between the PMT and the pressure-adjusting valve becomes too long and the height of the whole etching device is largely changed. Thus, a few mm to several tens of mm is desirable. Therefore, it is desirable that F is higher than about 10 kHz.

It should be noted that if detection of the foreign particles is highly expected in the detection process S205 of the foreign particles in FIG. 4, it is desirable that P is slightly larger than 100 mW/mm², for example, P=500 mW/mm² in the laser power density. In addition, plasma light entering the light collecting optical system is weaker than the stray light, CW laser can be used instead of pulse laser. However, it is difficult to detect the foreign particles in the process of S205 in this case.

It should be noted that the present invention can be applied to a plasma processing apparatus including a pressure-adjusting valve, namely, a plasma etching processing apparatus and a CVD processing apparatus.

As described above, according to the present invention, an image obtained by the I-CCD camera is processed by the image processing program. If a substantially-straight pixel line is present, in other words, the plural pixels connected in a substantially straight line are detected on the basis of the states of the signal intensities of the respective pixels, it is determined that the foreign particles are present. Therefore, it is possible to easily detect the foreign particles with a particle diameter of 100 nm or smaller. In addition, measurement of the number of foreign particles using a wafer for inspection is not necessary, and the level of the foreign particles can be constantly monitored with required accuracy.

### COMPARATIVE EXAMPLE

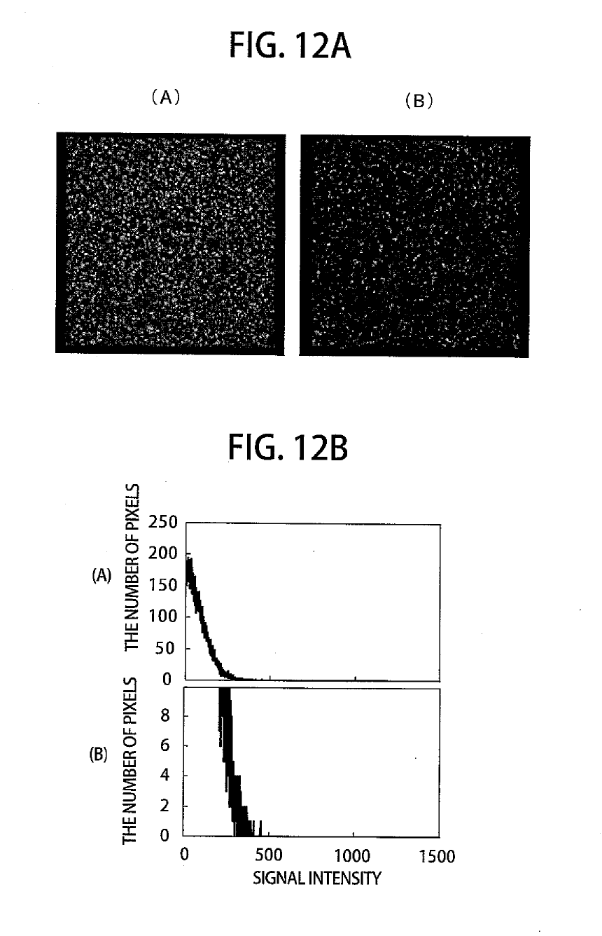

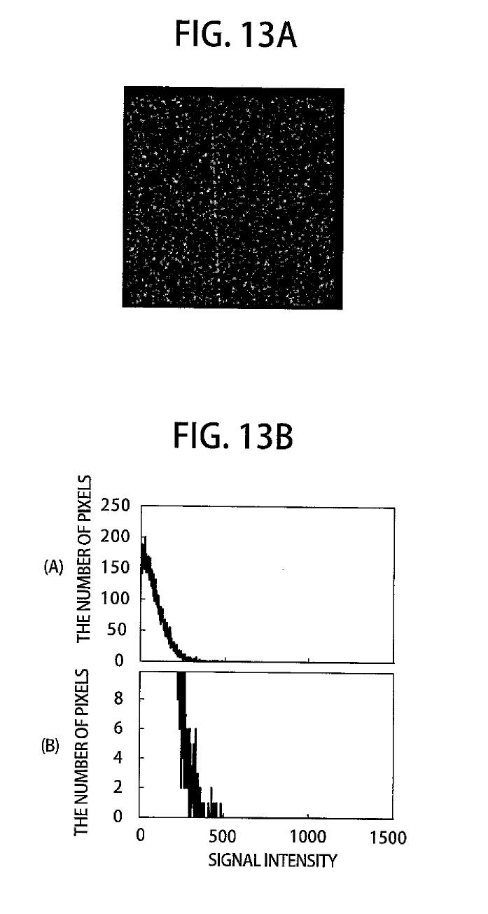

Next, as a comparative example to the first embodiment of the subject invention, there will be simply described an image processing method in which an image without the foreign particles is subtracted from one detected by the I-CCD camera 103. (A) of FIG. 12A shows another image capturing background light similar to FIG. 5A. (B) of FIG. 12A shows an image obtained by subtracting the image (A) of FIG. 12 from the image of FIG. 5A. In the result of subtraction, the pixels with minus signal intensities are shown in black as a signal intensity of 0. FIG. 12B shows a relation between a signal intensity and the number of pixels in (B) of FIG. 12A. FIG. 13A shows an image obtained by subtracting the image (A) of FIG. 12A from FIG. 8A. Further, FIG. 13B shows a relation between a signal intensity and the number of pixels in the image of FIG. 13A.

As being apparent from the comparison between FIG. 13B and FIG. 12B, a significant difference can not be found in both images. Specifically, a process of subtracting background light from the detected image is not very effective in enhancing the detection sensitivity of the foreign particles, but the process adversely affects in some cases. This is because noise signals caused by the scattered light show random distribution, and if an image with random distribution is subtracted from another image with random distribution, only an image with random distribution is obtained as a result. Specifically, if the intensity of the stray light is relatively weak as in the case where the average number of photons per one pixel is 1, subtraction of an image without the foreign particles from an image capturing the foreign particles can not enhance the detection accuracy of the foreign particles.

### Second Embodiment

Next, there will be described an example as a second embodiment in which a light detector such as the PMT or the I-CCD without spatial resolution described in the first embodiment is used in detection of the foreign particles. A plasma processing apparatus according to the embodiment includes a processing chamber, a high-frequency electric power for generating plasma, a gas supplying unit for supplying a gas, a gas exhaust unit for reducing the pressure of the inside of the processing chamber, a pressure-adjusting valve for adjusting the pressure of the inside of the processing chamber, and a sample stage on which a processing target is placed. In the plasma processing apparatus, laser light is allowed to transmit immediately beneath a gap generated when the pressure-adjusting valve adjusts the pressure of the inside of the processing chamber, and plural light detectors such as PMTs observe different areas. When the plural light detectors detect signals with a predetermined intensity or larger at a predetermined time difference, it is determined that foreign particles are detected. Hereinafter, the embodiment will be described in detail.

For example, it is difficult for a detector without position resolution such as a photomultiplier tube (PMT) to determine detection of the foreign particles without some modifications in the case of observing the same range of 10 mm×10 mm even under the measurement conditions shown in FIG. 7. The reason is as follows. Since the velocity of the foreign particles is about 0.5 m/s, the image of FIG. 7A can be obtained during at least about 20 ms of the exposure time of the I-CCD. The number of laser shots during 20 ms is 200. Since the number of photons of the stray light entering the light collecting optical system is 40000, the number of photons of incident stray light per one laser shot is 200. On the other hand, the number of photons of the scattered light which is caused by the foreign particles and enters the light collecting optical system is 5 per one laser shot. Accordingly, even if it is determined that the foreign particles are detected every one laser shot, the stray light is stronger 40 times. Therefore, the signals of the foreign particles are buried in noises caused by the stray light. If the observed range is reduced to one four-hundredth, namely, as small as 0.5 mm×0.5 mm, the average number of photons of the stray light entering the light collecting optical system is 0.5 per one laser shot. On the other hand, since the average number of photons of incident scattered light caused by the foreign particles is 5, the scattered light caused by the foreign particles is stronger about 10 times, resulting in easy detection of the foreign particles.

Specifically, in the case of using a detector without position resolution, it is necessary to decrease the stray light or to narrow the observed range. However, if the Rayleigh scattering caused by a gas is the dominant factor of the stray light, reduction of a gas pressure can decrease the stray light, which is not easy due to necessity of changes of the plasma processing conditions. On the other hand, narrowing the observed area leads to reduction of the probability that the foreign particles pass through the observed area and disadvantageously decreases a detection ratio.

In order to increase a detection ratio by observing a wide range while using a light detector without position resolution, it is necessary to divide the observed area into plural areas and to observe the respective different areas using plural detectors. However, this configuration is the same as a case in which a detector with position resolution is provided. In the case where the delivering direction and velocity of the foreign particles can be predicted to some extent, two or more detectors are used to observe different areas and detection of the foreign particles may be determined on the basis of a time difference between signals obtained by two or more detectors.

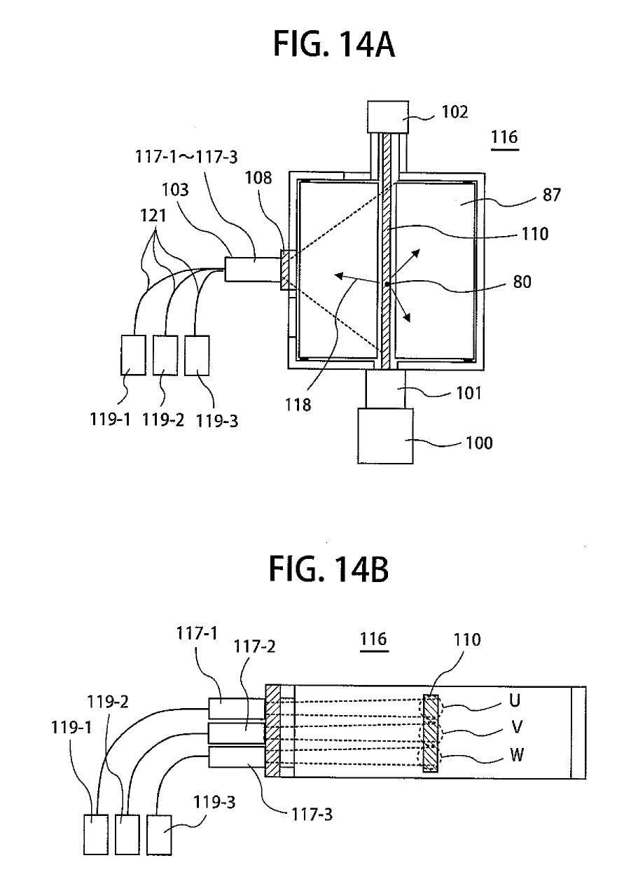

This example is shown in FIG. 14 (FIGS. 14A and 14B). FIG. 14A is a general top cross-sectional view of the apparatus in which the observed area is divided into plural areas, and FIG. 14B is a general side cross-sectional view thereof. In this embodiment, the laser light is allowed to transmit immediately beneath a gap generated when the pressure-adjusting valve adjusts the pressure of the inside of the processing chamber, and different areas are observed by the plural light detectors. If the plural light detectors detect signals with a predetermined intensity or larger at a predetermined time difference, it is determined that the foreign particles are detected.

Specifically, the rectangular laser light 110 whose cross section is longer in the height direction is allowed to pass immediately beneath the gap between two flappers 87, and the foreign particle 80 is observed in an upper area U, a middle area V and a lower area W of the laser light at equal intervals using three light collecting optical systems 117-1 to 117-3. The light collected by the light collecting optical system is measured by light detectors 119-1 to 119-3 using PMTs through optical fibers 121.

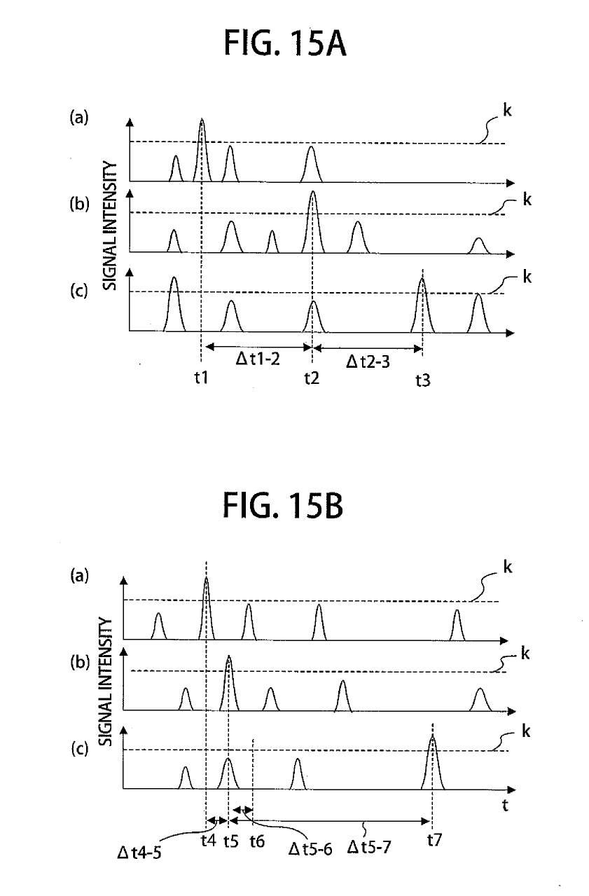

FIG. 15 (FIGS. 15A and 15B) shows an example of time changes of signals by three detectors. FIG. 15A shows a case in which the foreign particle 80 is captured, and FIG. 15B shows an example of signals only by background light. The horizontal axis represents a time, and the vertical axis represents a signal intensity. In FIG. 15, a dotted line k represents a threshold value for distinguishing a signal by detection of the foreign particles from a noise by the stray light. In FIG. 15A, when the foreign particle 80 enters the upper area U of the laser light 110 at a time t1, the detector 119-1 observing the area U detects a signal by light stronger than average stray light. When the foreign particle reaches the observed area V at a time t2, the detector 119-2 observing the area V detects light lager than the threshold value k. At t3 when a time Δt2−3 similar to a time difference Δt1−2 between t2 and t1 elapses (=Δ(t1−t2)), the foreign particles reach the observed area W. At this time, the detector 119-3 observing the area W detects an optical signal with the threshold value k or larger. This is because the movement of the foreign particle 80 forms a substantially straight line, and the velocity thereof is not largely changed. Thus, the scattered light caused by the foreign particle can be detected in order by three detectors at equal time intervals.

On the other hand, as shown in FIG. 15B, even if the detector 119-1 detects a signal exceeding the threshold value k at a time t4, and then the detector 119-2 detects a signal exceeding the threshold value k at a time 5, the detector 119-3 does not detect a signal exceeding the threshold value at a time t6 after a time Δt5−6 corresponding to a time difference Δt4−5 between t4 and t5 elapses (=Δ(t4−t5)). Then, the detector 119-3 captures a signal exceeding the threshold value k at a time t7 after a time Δt5−7 which is largely different from Δt4−5 elapses. In such a case, a set of obtained signals are not caused by the foreign particles, and are determined as signals caused by random stray light. As described above, it is possible to enhance the detection sensitivity of the foreign particles by considering a time difference of signals measured in plural detection areas.

It should be noted that the observed areas U, V, and W may not be necessarily arranged at equal intervals. In the case where the observed areas are not arranged at equal intervals, it may be determined whether or not a signal exceeding the threshold value is detected at a timing difference in accordance with intervals. Further, in the case where the velocity of the gas flow is largely changed in the observed areas, the detection timing of the foreign particles differs. In this case, it is desirable to predict the detection timing in accordance with the velocity of the gas flow in advance. For example, in the case where the velocity of the gas flow between U and V is faster than that between V and W by about 10%, the time required for the foreign particles to move from the area U to the area V is shorter than that from the area V to W by about 10%. Accordingly, in such a case, when the following formula (3) is satisfied, it may be determined that the foreign particles are detected.

Δt₁₋₂≈1.1×Δt₂₋₃ (3)

According to the embodiment, the detection unit and the detection optical system are provided so as to make the delivering direction of the foreign particles in a substantially straight line. When the intensity of the obtained signal corresponds to the signal intensity predicted on the basis of the delivering velocity of the foreign particles, it is determined that the foreign particles are detected. Accordingly, it is possible to easily detect the foreign particles with a particle diameter of 100 nm or smaller.

### Third Embodiment

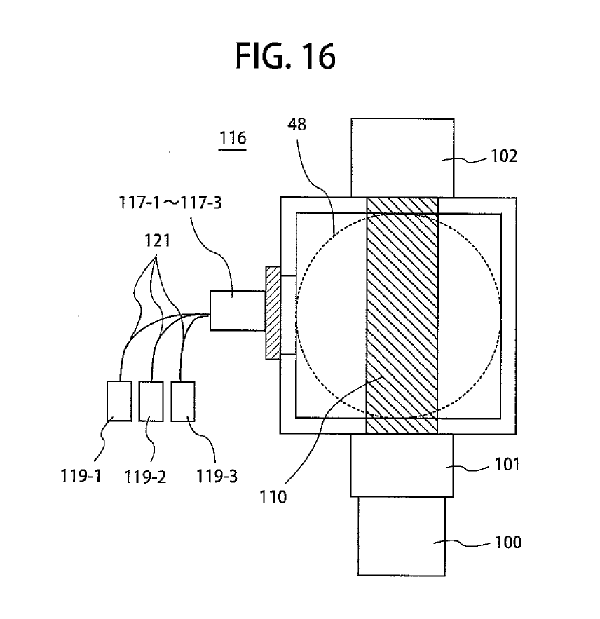

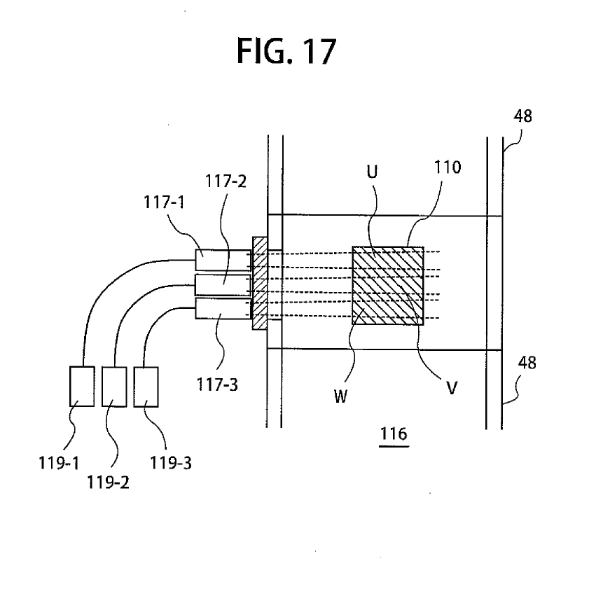

The measurement described in the second embodiment can be applied to, for example, detection of the foreign particles passing through an exhaust line. This example is shown in FIG. 16 and FIG. 17 as a third embodiment of the present invention. A plasma processing apparatus according to the embodiment includes a processing chamber, a high-frequency electric power for generating plasma, a gas supplying unit for supplying a gas, a gas exhaust unit for reducing the pressure of the inside of the processing chamber, a pressure-adjusting valve for adjusting the pressure of the inside of the processing chamber, and a sample stage on which a processing target is placed. In the plasma processing apparatus, laser light is allowed to pass through a gas exhaust line connecting the processing chamber with the gas exhaust unit, and plural light detectors for observing plural areas are provided. When the plural light detectors detect signals with a predetermined intensity or larger at predetermined intervals of timing, it is determined that the foreign particles are detected. Hereinafter, the embodiment will be described in detail.

FIG. 16 is a top cross-sectional view of the exhaust line 48 and the particle monitor unit 116, and FIG. 17 is a cross-sectional view of the exhaust line. The laser light 110 is allowed to pass through the exhaust line 48, the observed area is divided into three areas U, V, and W, and the detectors 119-1, 119-2, and 119-3 observing the respective areas determines detection of signals with a predetermined intensity or larger at a predetermined time difference. Accordingly, the detection sensitivity of the foreign particles can be enhanced.

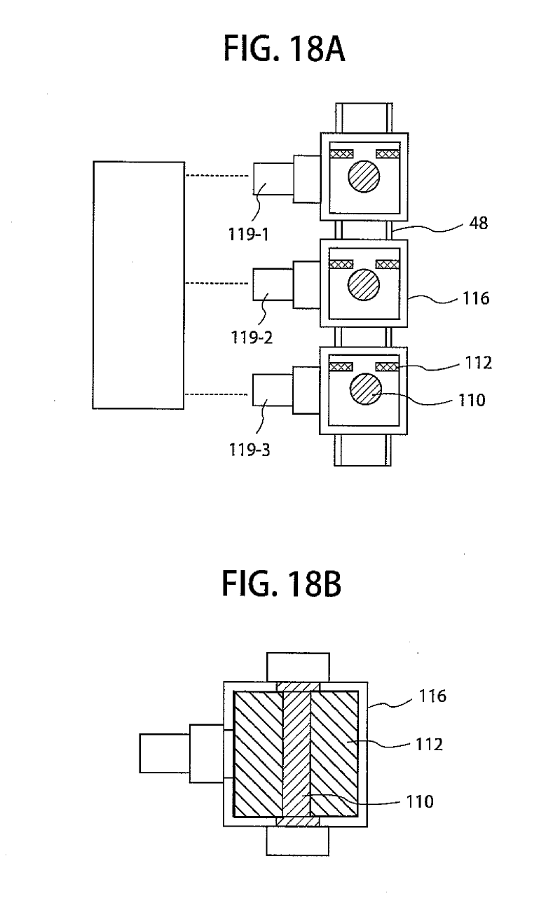

Further, as shown in FIG. 18 (FIG. 18A is a side view of the exhaust line 48 and the particle monitor unit 116, and FIG. 18B is a top view thereof), plural foreign particle detectors, each including one detector 119 and one laser light source 110, are provided in series at the exhaust line 48, and a time difference between signals from the respective detectors may be monitored. In addition, in order to increase the probability that the foreign particles pass through the laser light, flow controlling plates 112 may be provided so as to adjust the flow direction of the foreign particles. Further, although the pulse driving laser is used for the laser light source, CW laser may be used if background light by plasma is not present or is negligible.

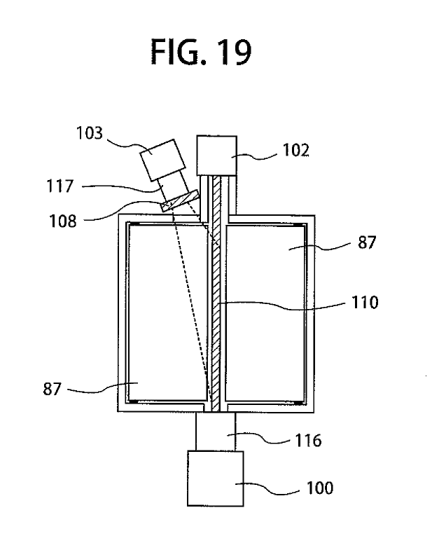

In the above-described embodiments, the light collecting optical system is provided in the direction orthogonal to the laser light 110. However, the band-pass filter 108, the light collecting optical system 117, and the I-CCD camera 103 are arranged at positions obliquely intersecting with the optical axis of the laser light 110 as shown in FIG. 19, and the front side of the scattered light caused by the foreign particles may be measured. It is obvious that the detector may be provided so as to measure the back side of the scattered light.

According to the embodiment, the detection unit and the detection optical system are provided so as to make the delivering direction of the foreign particles in a substantially straight line. When the intensity of the obtained signal corresponds to the signal intensity predicted on the basis of the delivering velocity of the foreign particles, it is determined that the foreign particles are detected. Accordingly, it is possible to easily detect the foreign particles with a particle diameter of 100 nm or smaller.

What is claimed is:

1. A plasma processing apparatus including a processing chamber, a high-frequency electric power that generates plasma, a gas supplying unit that supplies a gas, a gas exhaust unit that reduces the pressure of the inside of the processing chamber through a gas exhaust line, a pressure-adjusting valve that adjusts the pressure of the inside of the processing chamber, and a sample stage on which a processing target is placed, the apparatus comprising:
a laser light source that allows laser light to transmit through an exhaust gas flowing in the gas exhaust line;
an I-CCD camera that detects scattered light caused by foreign particles passing in the laser light; and
a foreign particle determination and detection unit that detects the foreign particles from an image measured by the I-CCD camera, wherein
the foreign particle determination and detection unit determines that the foreign particles are detected from the measured image when a plurality of pixels with signals having a predetermined intensity or larger are connected in a substantially straight line.

2. The plasma processing apparatus according to claim 1, wherein
in the case where the pixels with the predetermined signal intensity or larger are present across a predetermined length at predetermined pitches or shorter in a rectangular area with a predetermined width along an arbitrary axis in the measured image, the foreign particle determination and detection unit determines that the plurality of pixels with signals having the predetermined intensity or larger are connected in a substantially straight line.

3. The plasma processing apparatus according to claim 1, wherein
if the image measured by the I-CCD camera is processed by an image processing program and a substantially-straight pixel line is detected on the basis of the states of signal intensities of the respective pixels, the foreign particle determination and detection unit determines that the foreign particles are present.

4. The plasma processing apparatus according to claim 1, wherein
in the case where the pixels with the predetermined signal intensity are arranged at substantially-equal intervals on a substantially straight line in the measured image, the foreign particle determination and detection unit determines that the foreign particles are detected.

5. The plasma processing apparatus according to claim 4, wherein
when the pixels with signals having the predetermined intensity or larger are connected in a substantially straight line in the measured image, the foreign particle determination and detection unit estimates the velocity of the foreign particles on the basis of intervals of the pixels with signals having the predetermined intensity or larger in the pixels on the substantially straight line, and determines that the foreign particles are detected when the estimated velocity of the foreign particles is similar to the velocity of gas flow.

6. The plasma processing apparatus according to claim 1, wherein
on the basis of determination on whether or not the total value of the signal intensities of all pixels exceeds a certain threshold value, the foreign particle determination and detection unit detects the foreign particles before determination on whether or not the plurality of pixels with signals having the predetermined intensity or larger are connected in a substantially straight line.

7. The plasma processing apparatus according to claim 1,
wherein the intensity of Rayleigh scattering light caused by a gas existing in the processing chamber is estimated in accordance with the pressure of the inside of the processing chamber, a threshold value that distinguishes a signal by the foreign particles from a noise signal is adjusted,
wherein the laser light is allowed to transmit immediately beneath a gap generated when the pressure-adjusting valve adjusts the pressure of the inside of the processing chamber, and
wherein the scattered light caused by the foreign particles passing in the laser light is measured by the I-CCD camera.

8. The plasma processing apparatus according to claim 1,
wherein the power density of the laser light in an observed area is at least 10 mW/mm² or larger at a position where the power density is the largest, pulse oscillation laser is used for the laser light source, and
wherein the laser power density, a position where a light collecting optical system is provided, and the diameter of an objective lens of the light collecting optical system are adjusted, so that the average number of photons entering the light collecting optical system for detecting the scattered light caused by particles with a particle diameter of 80 nm is 1 in one laser pulse.

9. A foreign particle detecting method in a plasma processing apparatus including a processing chamber, a high-frequency electric power that generates plasma, a gas supplying unit that supplies a gas, a gas exhaust unit that reduces the pressure of the inside of the processing chamber through a gas exhaust line, a pressure-adjusting valve that adjusts the pressure of the inside of the processing chamber, and a sample stage on which a processing target is placed, the plasma processing apparatus comprises,
a laser light source that allows laser light to transmit through an exhaust gas flowing in the gas exhaust line;
an I-CCD camera that detects scattered light caused by foreign particles passing in the laser light; and
a foreign particle determination and detection unit that detects the foreign particles from an image measured by the I-CCD camera,
wherein the foreign particle detecting method comprising steps of:
allowing the laser light to transmit immediately beneath a gap generated when the pressure-adjusting valve adjusts the pressure of the inside of the processing chamber;
measuring the scattered light caused by the foreign particles passing in the laser light using the I-CCD camera; and
determining that the foreign particles are detected from the measured image when a plurality of pixels with signals having a predetermined intensity or larger are connected in a substantially straight line.

10. The foreign particle detecting method in a plasma processing apparatus according to claim 9,
when the pixels with the predetermined signal intensity or larger are present across a predetermined length at predetermined pitches or shorter in a rectangular area with a predetermined width along an axis corresponding to the flow of the exhaust gas in the measured image, determining that the plurality of pixels with signals having the predetermined intensity or larger are connected in a substantially straight line.
